(19) United States
(12) Patent Application Publication
(10) Pub. No.: US 2026/0366140 A1
(43) Pub. Date: Nov. 19, 2026

(54) 4D PRINTED DYNAMIC SELF-HEALING KAPTON MASK

(71) Applicant: International Business Machines Corporation, Armonk, NY (US)

(72) Inventors: Heather Nicole POLGREAN, Lagrangeville, NY (US); Jessica NAHULAN, Vaughan (CA); Jeremy R. FOX, Georgetown, TX (US); Tiberiu SUTO, Franklin, NY (US)

(21) Appl. No.: 19/211,620

(22) Filed: May 19, 2025

(51) Int. Cl. C23C 16/04; B33Y 80/00

(52) U.S. Cl. CPC C23C 16/042; B33Y 80/00

(57) ABSTRACT

In some implementations, a computer system may fabricate a dynamic Kapton mask using four-dimensional (4D) printing, the Kapton mask comprising smart materials that respond to environmental stimuli. The computer system may embed a self-healing polymer within the Kapton mask that is capable of automatically repairing physical damage that occurs during manufacturing or use. The computer system may integrate a sensor and a control system within the Kapton mask that are capable of monitoring conditions and adjusting properties of the Kapton mask in real-time.

### BACKGROUND

This disclosure relates to four-dimensional (4D) printing, and more specifically, to 4D printing of a mask.

### SUMMARY

Some aspects described herein relate to a method. The method may include fabricating a dynamic Kapton mask using 4D printing, the Kapton mask comprising smart materials that respond to environmental stimuli. The method may include embedding a self-healing polymer within the Kapton mask that is capable of automatically repairing physical damage that occurs during manufacturing or use. The method may include integrating a sensor and a control system within the Kapton mask that are capable of monitoring conditions and adjusting properties of the Kapton mask in real-time.

Some aspects described herein relate to a device. The device may include a Kapton mask that includes smart materials configured to respond to external stimuli that include temperature, pressure, or ultraviolet light, where the Kapton mask includes a self-healing polymer capable of repairing physical damage caused by manufacturing or use. The device may include a set of sensors integrated into the Kapton mask that are configured to monitor, during the manufacture or use, environmental conditions that include temperature, pressure, and contamination level.

Some aspects described herein relate to a computer program product. The computer program product may include one or more computer-readable storage media and program instructions stored on the one or more computer-readable storage media to perform operations. The operations may include fabricating, by 4D printing, a dynamic Kapton mask having a substrate made of Kapton material and embedded smart materials responsive to temperature, pressure, or ultraviolet light, where the Kapton mask includes a self-healing polymer capable of automatically repairing physical damage caused by manufacturing or use. The operations may include adjusting, using a sensor and a control system, physical properties of the Kapton mask based on real-time data from the sensor.

### BRIEF DESCRIPTION OF THE DRAWINGS

FIG. 1 is a diagram of an example computing environment for a 4D printed Kapton mask.

FIG. 2 is a diagram of an example implementation associated with a Kapton mask exhibiting variable shape configurations.

FIG. 3 is a diagram of an example implementation associated with using a Kapton mask for manufacturing.

FIG. 4 is a diagram illustrating an example of adjusting the Kapton mask.

FIG. 5 is a diagram illustrating an example of a self-healing crack.

FIG. 6 is a flowchart of an example process associated with a 4D printed dynamic self-healing Kapton mask.

FIG. 7 is a flowchart of an example process associated with a 4D printed dynamic self-healing Kapton mask.

### DETAILED DESCRIPTION

The following detailed description of example implementations refers to the accompanying drawings. The same reference numbers in different drawings may identify the same or similar elements.

According to an aspect, there is provided a computer-implemented method that includes fabricating a dynamic Kapton mask using four-dimensional (4D) printing, the Kapton mask including smart materials that respond to environmental stimuli. The method includes embedding a self-healing polymer within the Kapton mask that is capable of automatically repairing physical damage that occurs during manufacturing or use. The method includes integrating a sensor and a control system within the Kapton mask that are capable of monitoring conditions and adjusting properties of the Kapton mask in real-time. As a result, the method enables the creation of a dynamic Kapton mask that can adapt to changing environmental conditions, enabling improved precision in semiconductor manufacturing processes and reducing the need for manual intervention or replacement of the Kapton mask. Additionally, or alternatively, the use of self-healing polymers and smart materials extends the lifespan of the Kapton mask and enables efficient use of the mask in various deposition processes.

In embodiments, the method includes using the Kapton mask in a manufacturing process, where the Kapton mask is capable of adapting to changing environmental conditions during the manufacturing or use. This may enable real-time adjustments to deposition parameters to ensure optimal results, which can be particularly useful for complex semiconductor manufacturing processes that require precise control over deposition conditions.

For example, in a semiconductor manufacturing process, a dynamic Kapton mask fabricated using 4D printing can adapt to changing environmental conditions by autonomously adjusting its shape, aperture size, or material permeability in real-time. This allows for optimal deposition results and improved yield, as the mask can respond to changes in temperature, pressure, or other environmental factors.

In embodiments, the method includes using the Kapton mask to perform 4D printing of an object. As a result, the Kapton mask can be used to create objects with complex geometries or structures that cannot be achieved using traditional manufacturing methods.

In a technical use case, the dynamic Kapton mask can be used to fabricate complex semiconductor circuits and microelectromechanical systems devices that require precise control over material deposition. By adjusting its aperture size and shape in real-time, the Kapton mask can ensure optimal deposition results and improved yield.

In embodiments, the method includes adjusting, using the sensor and the control system, an aperture size and a shape of the Kapton mask in real-time. This enables the Kapton mask to be adjusted dynamically to accommodate different deposition requirements or changing environmental conditions, which can help ensure optimal deposition results.

In a semiconductor manufacturing scenario, the real-time adjustment of aperture size and shape enables the Kapton mask to optimize material deposition in response to changes in deposition conditions, resulting in improved yield and reduced waste.

In embodiments, the Kapton mask is scalable for use in semiconductor manufacturing processes, and the Kapton mask is capable of adapting to changing environmental conditions to ensure precise deposition control. As a result, the Kapton mask can be used in a wide range of semiconductor manufacturing applications, from small-scale research and development to large-scale commercial production.

In a technical use case, the dynamic Kapton mask can be integrated with existing semiconductor manufacturing equipment, enabling improved precision and yield in high-volume production environments.

In embodiments, the control system uses real-time data from the sensor to adjust the properties to ensure the precise deposition control. This may include adjusting deposition parameters such as temperature, pressure, or deposition rate to ensure optimal results. For example, in a chemical vapor deposition (CVD) process, the dynamic Kapton mask can adjust its material permeability in real-time to optimize material deposition, resulting in improved yield and reduced waste.

In embodiments, the Kapton mask is capable of dynamically adjusting its material permeability for deposition and doping. As a result, the Kapton mask can be used to control the flow of materials during deposition processes, enabling improved precision and reducing waste. In a technical use case, the dynamic Kapton mask can be used to fabricate advanced semiconductor devices, such as 3D stacked devices or fin field-effect transistors (FinFETs), that require precise control over material deposition.

In embodiments, the self-healing polymer includes microcapsules containing a healing agent that is released upon crack formation. This enables the Kapton mask to automatically repair minor damage or cracks, extending its lifespan and reducing downtime. In a semiconductor manufacturing scenario, the self-healing property of the Kapton mask enables reduced maintenance and repair costs, as well as improved yield and productivity.

In embodiments, the Kapton mask has a dynamic thermal conductivity to adjust heat dissipation properties during high-energy deposition processes. This enables the Kapton mask to maintain a stable temperature, even during high-energy deposition processes, which can help prevent damage to the mask or the substrate. In a technical use case, the dynamic thermal conductivity of the Kapton mask enables improved thermal management during plasma-enhanced CVD (PECVD) processes, resulting in improved yield and reduced waste.

In embodiments, the method includes generating a digital twin of the Kapton mask to simulate behavior of the Kapton mask and to optimize a design of the Kapton mask. This may enable the simulation of various deposition scenarios, enabling the optimization of deposition parameters and the design of the Kapton mask to ensure optimal results.

In embodiments, the method includes predicting potential failure modes of the Kapton mask. Additionally, or alternatively, the method includes optimizing material selections such that material stresses are minimized. This may enable the identification of potential failure modes or weaknesses in the Kapton mask, enabling the design of the mask to be optimized to minimize these risks.

According to an aspect of the invention, there is provided a device. The device includes a Kapton mask that includes smart materials configured to respond to external stimuli that include temperature, pressure, or ultraviolet light, where the Kapton mask includes a self-healing polymer capable of repairing physical damage caused by manufacturing or use. The device includes a set of sensors integrated into the Kapton mask that are configured to monitor, during the manufacture or use, environmental conditions that include temperature, pressure, and contamination level. As a result, the device enables real-time monitoring of environmental conditions and adjustment of the Kapton mask to ensure optimal deposition results.

In embodiments, the device is configured to adjust a material permeability of the Kapton mask based on external electrical inputs or temperature. This enables the dynamic adjustment of material flow during deposition processes, enabling improved precision and reducing waste. In a technical use case, the device can be utilized in a semiconductor fabrication facility to enhance the efficiency and accuracy of deposition processes by dynamically adjusting the material permeability of the Kapton mask based on real-time environmental conditions.

In embodiments, the self-healing polymer is capable of automatically repairing physical damage caused by a deposition process, an etching process, or a plasma process. As a result, the device can automatically repair minor damage or cracks, extending its lifespan and reducing downtime. In a semiconductor manufacturing scenario, the device’s self-healing polymer properties contribute to reduced maintenance costs and increased operational efficiency by autonomously repairing damage during various semiconductor fabrication processes.

In embodiments, the Kapton mask includes dynamic thermal conductivity that is capable of adjustment of heat dissipation properties during high-energy deposition processes. This enables the device to maintain stable operating temperatures, even under high-energy deposition conditions. In a technical use case, the device’s dynamic thermal conductivity properties can be leveraged in advanced semiconductor fabrication processes to ensure consistent and controlled heat dissipation, resulting in improved product quality and reduced manufacturing defects.

In embodiments, the device is configured to generate a digital twin of the Kapton mask that simulates a dimensional stability of apertures in the Kapton mask. The digital twin may be used to simulate a dimensional stability of apertures in the Kapton mask when using different shape-memory alloys. The computer system may analyze stress distribution across materials when different properties of the shape-memory alloys are activated. The computer system may optimize material selections to minimize material stresses. By creating a virtual replica of the Kapton mask, it is possible to simulate the behavior of different shape-memory alloys and predict potential failure modes, such as radial cracking or circumferential yielding, that may occur during various manufacturing processes. This allows for the evaluation of different design scenarios and the optimization of material selections to minimize material stresses, ultimately improving the reliability of the Kapton mask.

Semiconductor manufacturing involves precise and complex deposition processes such as CVD, physical vapor deposition (PVD), and atomic layer deposition (ALD). These processes require masks that can accurately control the areas where materials are deposited onto a substrate. Kapton is a high-performance polyimide material known for its high thermal stability, making Kapton suitable for high-temperature deposition processes. Kapton is also an excellent electrical insulator, which is essential for preventing electrical interference or shorts during the deposition process. In addition, Kapton is a robust material that can withstand the mechanical stresses and strains associated with deposition processes. A Kapton mask is a thin sheet or layer of Kapton material that is patterned with specific designs or apertures to control the deposition of materials onto a substrate. The mask is placed between the substrate and the deposition source, allowing the deposited material to pass through the apertures and form the desired pattern on the substrate.

Traditional Kapton masks, commonly used for these applications, have limitations. Kapton masks are rigid and lack flexibility to adjust to different deposition conditions, leading to reduced efficiency and increased downtime for replacement. Moreover, Kapton masks are prone to wear and tear, limiting their functionality and requiring frequent replacements. Furthermore, existing masks are designed for single-step processes and cannot handle multiple functions (such as deposition and doping) within a single tool. This results in increased tool complexity, higher manufacturing costs, and reduced productivity. Additionally, traditional masks can be affected by thermal stress, leading to distortion and reduced accuracy during the deposition process.

In the context of semiconductor manufacturing, particularly in advanced nodes such as 2 nanometers and beyond, the need for high precision, adaptability, and reliability in deposition masks is important. However, the limitations of traditional Kapton masks pose significant technical challenges in achieving these goals. The lack of flexibility, durability, and multi-functionality in existing masks hinders the efficiency and cost-effectiveness of the semiconductor manufacturing process.

Some implementations described herein provide a dynamic Kapton mask for manufacturing and use, such as for semiconductor deposition processes. The Kapton mask includes a substrate made of Kapton material, smart materials embedded within the mask to respond to environmental stimuli, and a self-healing polymer to automatically repair physical damage. For example, the dynamic Kapton mask is fabricated using four-dimensional (4D) printing and integrates a sensor and a control system to adjust the properties of the mask in real-time. 4D printing refers to the process of creating three-dimensional (3D) objects that can change shape or function over time in response to environmental stimuli, such as temperature, light, or moisture, thereby adding a fourth dimension of time to the traditional 3D printing process. The Kapton mask can adjust its aperture size and shape, dynamically change its material permeability for deposition and doping, and incorporate dynamic thermal conductivity to maintain structural stability.

In this way, the dynamic Kapton mask reduces latency in manufacturing processes (e.g., semiconductor manufacturing processes) by integrating multiple functions in a single tool. This reduction in tool changes results in a decrease in processing downtime. Additionally, the dynamic Kapton mask’s self-healing capabilities reduce the frequency of physical damage-induced replacements, resulting in increased tool availability and reducing maintenance requirements. The mask’s adaptive structure also minimizes material stresses caused by thermal expansion and contraction during deposition, thus reducing defect rates. Furthermore, the mask’s ability to dynamically adjust to changing environmental conditions enables precise deposition control, leading to improved uniformity in semiconductor production. In this way, the dynamic Kapton mask may conserve processing resources, reduce energy consumption, reduce material waste, and/or the like.

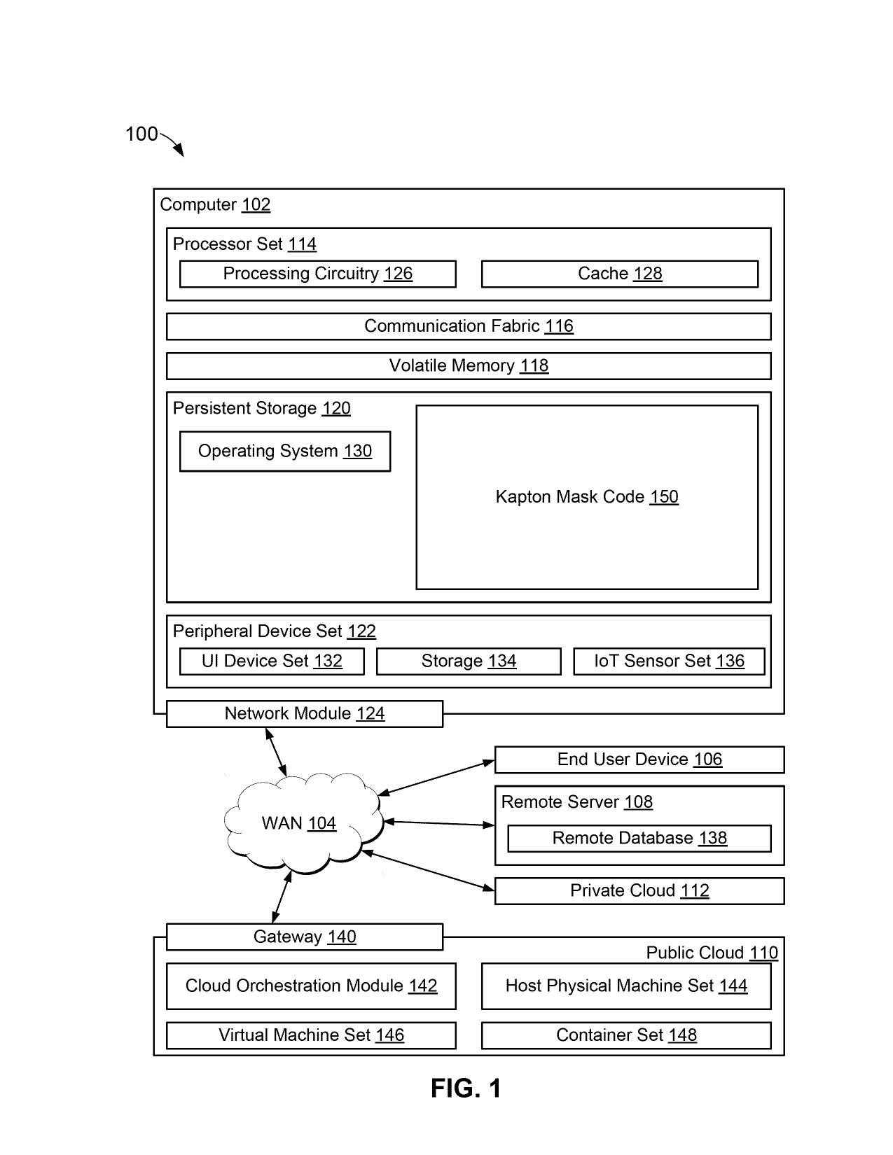

FIG. 1 is a diagram of an example computing environment 100 for a 4D printed Kapton mask.

The computing environment 100 contains an example of an environment for the execution of at least some of the computer code involved in performing the inventive methods, such as Kapton mask code 150. In addition to the Kapton mask code 150, the computing environment 100 includes, for example, a computer 102, a wide area network (WAN) 104, an end user device (EUD) 106, a remote server 108, a public cloud 110, and a private cloud 112. In this embodiment, the computer 102 includes a processor set 114 (including processing circuitry 126 and a cache 128), communication fabric 116, volatile memory 118, persistent storage 120 (including an operating system 130 and the Kapton mask code 150, as identified above), a peripheral device set 122 (including a user interface (UI) device set 132, storage 134, and an Internet of Things (IoT) sensor set 136), and a network module 124. The remote server 108 includes a remote database 138. The public cloud 110 includes a gateway 140, a cloud orchestration module 142, a host physical machine set 144, a virtual machine set 146, and a container set 148.

The computer 102 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as the remote database 138. As is well understood in the art of computer technology, and depending upon the technology, performance of a computer-implemented method may be distributed among multiple computers and/or between multiple locations. On the other hand, in this presentation of the computing environment 100, detailed discussion is focused on a single computer, specifically the computer 102, to keep the presentation as simple as possible. The computer 102 may be located in a cloud, even though it is not shown in a cloud in FIG. 1. On the other hand, the computer 102 is not required to be in a cloud except to any extent as may be affirmatively indicated.

The processor set 114 includes one, or more, computer processors of any type now known or to be developed in the future. The processing circuitry 126 may be distributed over multiple packages, for example, multiple, coordinated integrated circuit chips. The processing circuitry 126 may implement multiple processor threads and/or multiple processor cores. The cache 128 is memory that is located in the processor chip package(s) and is typically used for data or code that should be available for rapid access by the threads or cores running on the processor set 114. Cache memories are typically organized into multiple levels depending upon relative proximity to the processing circuitry. Alternatively, some, or all, of the cache for the processor set may be located “off chip.” In some computing environments, the processor set 114 may be designed for working with qubits and performing quantum computing. Computer-readable program instructions are typically loaded onto the computer 102 to cause a series of operational steps to be performed by the processor set 114 of the computer 102 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as the cache 128 and the other storage media discussed below. The program instructions, and associated data, are accessed by the processor set 114 to control and direct performance of the inventive methods. In the computing environment 100, at least some of the instructions for performing the inventive methods may be stored in Kapton mask code 150 in the persistent storage 120.

The communication fabric 116 is the signal conduction path that allows the various components of the computer 102 to communicate with each other. Typically, this fabric is made of switches and electrically conductive paths, such as the switches and electrically conductive paths that make up buses, bridges, and/or physical input / output ports, among other examples. Other types of signal communication paths may be used, such as fiber optic communication paths and/or wireless communication paths, among other examples.

The volatile memory 118 is any type of volatile memory now known or to be developed in the future. Examples include dynamic type random access memory (RAM) or static type RAM. Typically, the volatile memory 118 is characterized by random access, but this is not required unless affirmatively indicated. In the computer 102, the volatile memory 118 is located in a single package and is internal to the computer 102, but, alternatively or additionally, the volatile memory 118 may be distributed over multiple packages and/or located externally with respect to the computer 102.

The persistent storage 120 is any form of non-volatile storage for computers that is now known or to be developed in the future. The non-volatility of this storage means that the stored data is maintained regardless of whether power is being supplied to the computer 102 and/or directly to the persistent storage 120. The persistent storage 120 may be a read only memory (ROM), but typically at least a portion of the persistent storage allows writing of data, deletion of data and re-writing of data. Some familiar forms of persistent storage include magnetic disks and solid state storage devices. The operating system 130 may take several forms, such as various known proprietary operating systems or open source Portable Operating System Interface-type operating systems that employ a kernel. The code included in the Kapton mask code 150 typically includes at least some of the computer code involved in performing one or more operations described herein. The operations may include, for example, fabricating a dynamic Kapton mask using 4D printing, the Kapton mask comprising smart materials that respond to environmental stimuli; embedding a self-healing polymer within the Kapton mask that is capable of automatically repairing physical damage that occurs during manufacturing or use; and integrating a sensor and a control system within the Kapton mask that are capable of monitoring conditions and adjusting properties of the Kapton mask in real-time.

In some implementations, a device may include a Kapton mask that includes smart materials configured to respond to external stimuli that include temperature, pressure, or ultraviolet light, wherein the Kapton mask includes a self-healing polymer capable of repairing physical damage caused by manufacturing or use; and a set of sensors integrated into the Kapton mask that are configured to monitor, during the manufacture or use, environmental conditions that include temperature, pressure, and contamination level.

In some implementations, the operations may include fabricating, by 4D printing, a dynamic Kapton mask having a substrate made of Kapton material and embedded smart materials responsive to temperature, pressure, or ultraviolet light, wherein the Kapton mask includes a self-healing polymer capable of automatically repairing physical damage caused by manufacturing or use; and adjusting, using a sensor and a control system, physical properties of the Kapton mask based on real-time data from the sensor.

The peripheral device set 122 includes the set of peripheral devices of the computer 102. Data communication connections between the peripheral devices and the other components of the computer 102 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, the UI device set 132 may include components such as a display screen, speaker, microphone, wearable devices (such as goggles and smart watches), keyboard, mouse, printer, touchpad, game controllers, and haptic devices. The storage 134 is external storage, such as an external hard drive, or insertable storage, such as an SD card. The storage 134 may be persistent and/or volatile. In some embodiments, the storage 134 may take the form of a quantum computing storage device for storing data in the form of qubits. In embodiments where the computer 102 is required to have a large amount of storage (for example, where the computer 102 locally stores and manages a large database), then this storage may be provided by peripheral storage devices designed for storing very large amounts of data, such as a storage area network (SAN) that is shared by multiple, geographically distributed computers. The IoT sensor set 136 is made up of sensors that can be used in Internet of Things applications. For example, one sensor may be a thermometer and another sensor may be a motion detector.

The network module 124 is the collection of computer software, hardware, and firmware that allows the computer 102 to communicate with other computers through the WAN 104. The network module 124 may include hardware, such as modems or Wi-Fi signal transceivers, software for packetizing and/or de-packetizing data for communication network transmission, and/or web browser software for communicating data over the internet. In some embodiments, network control functions and network forwarding functions of the network module 124 are performed on the same physical hardware device. In other embodiments (for example, embodiments that utilize software-defined networking (SDN)), the control functions and the forwarding functions of the network module 124 are performed on physically separate devices, such that the control functions manage several different network hardware devices. Computer-readable program instructions for performing the inventive methods can typically be downloaded to the computer 102 from an external computer or external storage device through a network adapter card or network interface included in the network module 124.

The WAN 104 is any wide area network (for example, the internet) capable of communicating computer data over non-local distances by any technology for communicating computer data, now known or to be developed in the future. In some embodiments, the WAN 104 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers, and/or edge servers, among other examples.

The EUD 106 is any computer system that is used and controlled by an end user (for example, a customer of an enterprise that operates the computer 102), and may take any of the forms discussed above in connection with the computer 102. The EUD 106 typically receives helpful and useful data from the operations of the computer 102. For example, in a hypothetical case where the computer 102 is designed to provide a recommendation to an end user, this recommendation would typically be communicated from the network module 124 of the computer 102 through the WAN 104 to the EUD 106. In this way, the EUD 106 can display, or otherwise present, the recommendation to an end user. In some embodiments, the EUD 106 may be a client device, such as thin client, heavy client, mainframe computer, and/or desktop computer, among other examples.

The remote server 108 is any computer system that serves at least some data and/or functionality to the computer 102. The remote server 108 may be controlled and used by the same entity that operates the computer 102. The remote server 108 represents the machine(s) that collect and store helpful and useful data for use by other computers, such as the computer 102. For example, in a hypothetical case where the computer 102 is designed and programmed to provide a recommendation based on historical data, then this historical data may be provided to the computer 102 from the remote database 138 of the remote server 108.

The public cloud 110 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of the public cloud 110 is performed by the computer hardware and/or software of the cloud orchestration module 142. The computing resources provided by the public cloud 110 are typically implemented by virtual computing environments that run on various computers making up the computers of the host physical machine set 144, which is the universe of physical computers in and/or available to the public cloud 110. The virtual computing environments (VCEs) typically take the form of virtual machines from the virtual machine set 146 and/or containers from the container set 148. It is understood that these VCEs may be stored as images and may be transferred among and between the various physical machine hosts, either as images or after instantiation of the VCE. The cloud orchestration module 142 manages the transfer and storage of images, deploys new instantiations of VCEs and manages active instantiations of VCE deployments. The gateway 140 is the collection of computer software, hardware, and firmware that allows the public cloud 110 to communicate through the WAN 104.

Some further explanation of VCEs will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

The private cloud 112 is similar to the public cloud 110, except that the computing resources are only available for use by a single enterprise. While the private cloud 112 is depicted as being in communication with the WAN 104, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, the public cloud 110 and the private cloud 112 are both part of a larger hybrid cloud.

Cloud computing services and/or microservices (not separately shown in FIG. 1): private cloud 112 and public clouds 110 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider’s systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of application programming interfaces (APIs). One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

In some implementations, a computer system (e.g., a computer 102) includes means for fabricating a dynamic Kapton mask using 4D printing, the Kapton mask comprising smart materials that respond to environmental stimuli; means for embedding a self-healing polymer within the Kapton mask that is capable of automatically repairing physical damage that occurs during manufacturing or use; or means for integrating a sensor and a control system within the Kapton mask that are capable of monitoring conditions and adjusting properties of the Kapton mask in real-time.

In some implementations, a computer system (e.g., a computer 102) includes means for fabricating, by 4D printing, a dynamic Kapton mask having a substrate made of Kapton material and embedded smart materials responsive to temperature, pressure, or ultraviolet light, the Kapton mask including a self-healing polymer capable of automatically repairing physical damage caused by manufacturing or use; and means for adjusting, using a sensor and a control system, physical properties of the Kapton mask based on real-time data from the sensor. In some aspects, the means for the computer system to perform operations described herein may include, for example, processor set 114, communication fabric 116, and volatile memory 118.

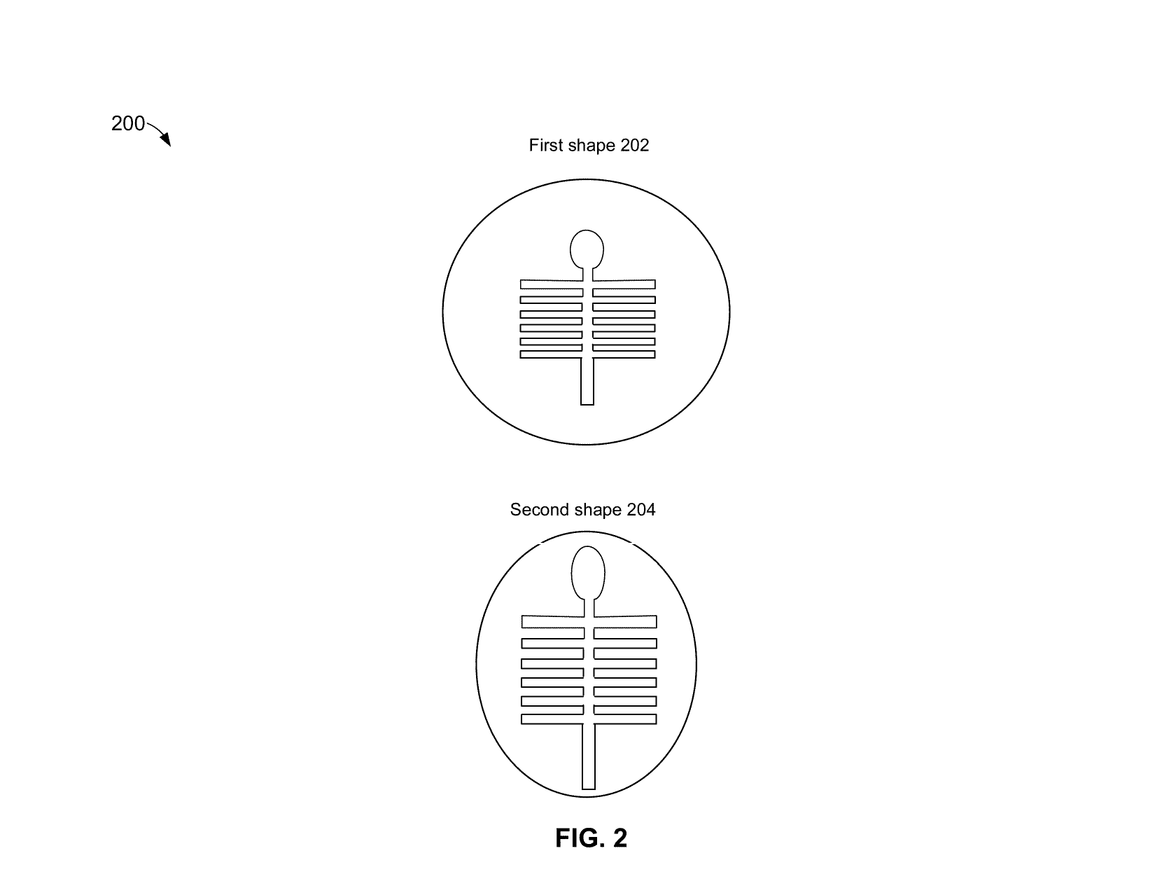

FIG. 2 is a diagram of an example implementation 200 associated with a Kapton mask exhibiting variable shape configurations. Example implementation 200 shows a dynamic Kapton mask capable of transitioning between different shapes. For example, the Kapton mask may exhibit a first shape 202, which illustrates an initial state of the mask that may be responsive to specific environmental stimuli such as temperature or pressure. The first shape 202 may represent a configuration suitable for a particular deposition process, offering optimized aperture size and pattern density to ensure precise material application.

The Kapton mask may include embedded smart materials that respond to stimuli, enabling adjustments in the physical structure of the mask as required by the fabrication process. The dynamic Kapton mask may transition to a second shape 204, indicating its ability to adapt in real-time to changing conditions during semiconductor manufacturing. The second shape 204 may represent an altered configuration of the mask’s apertures and overall geometry, allowing the mask to accommodate variations in deposition techniques or environmental conditions without the need for manual intervention. For example, the mask may expand or contract its apertures to optimize deposition quality in response to temperature fluctuations or changes in pressure. In example implementation 200, the Kapton mask has expanded in one direction.

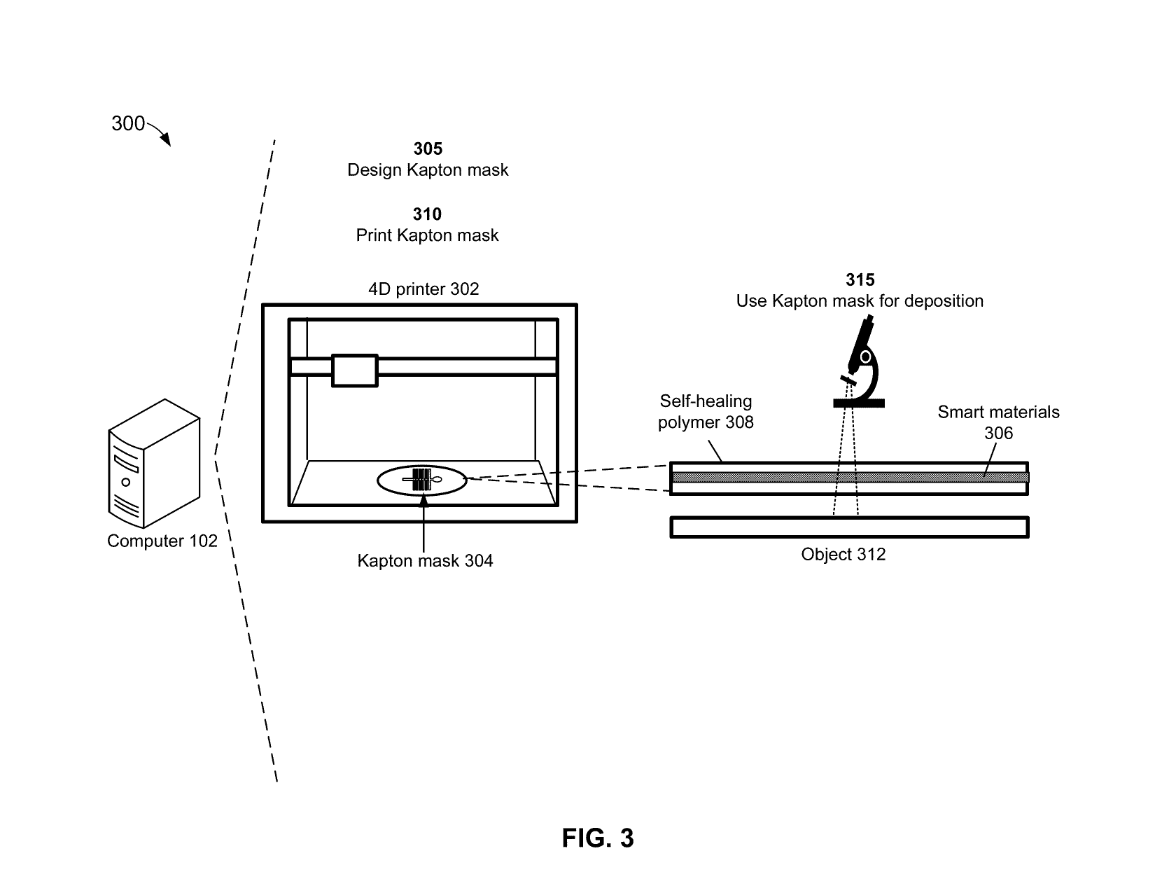

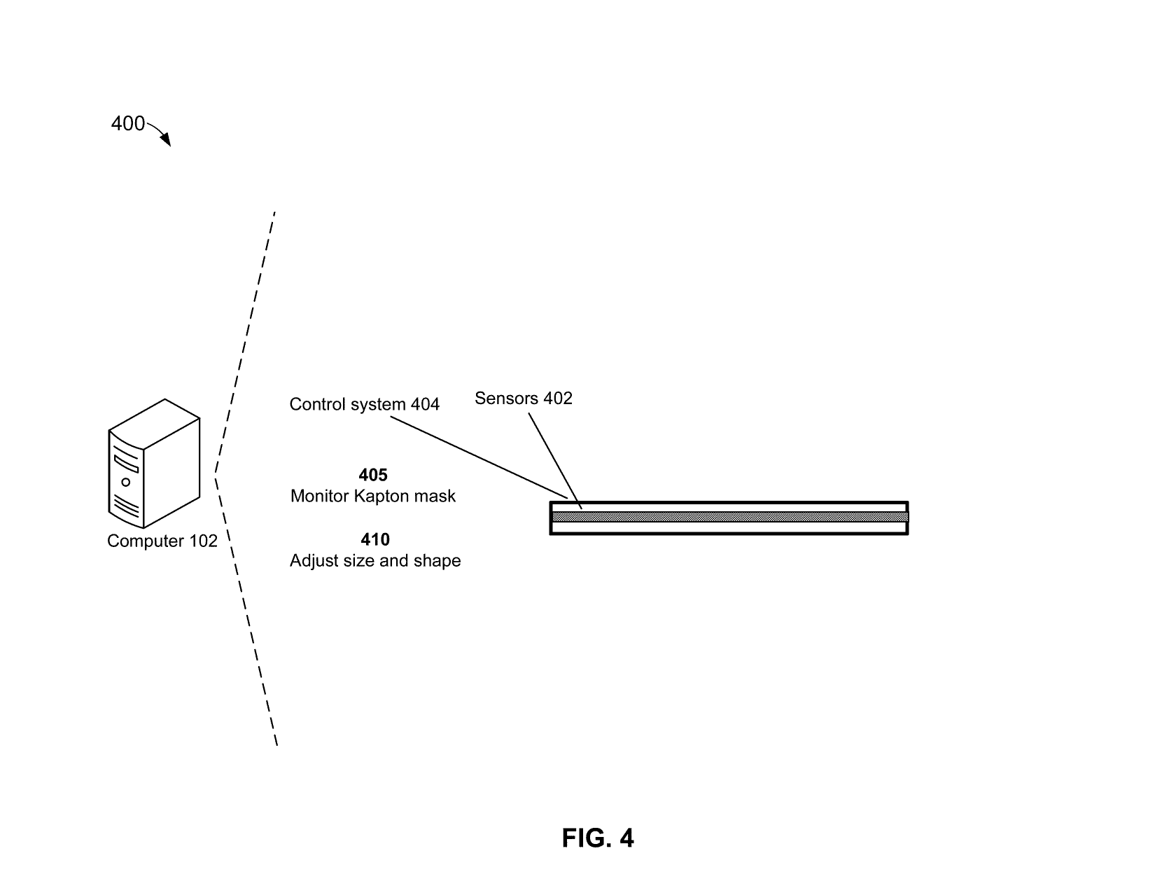

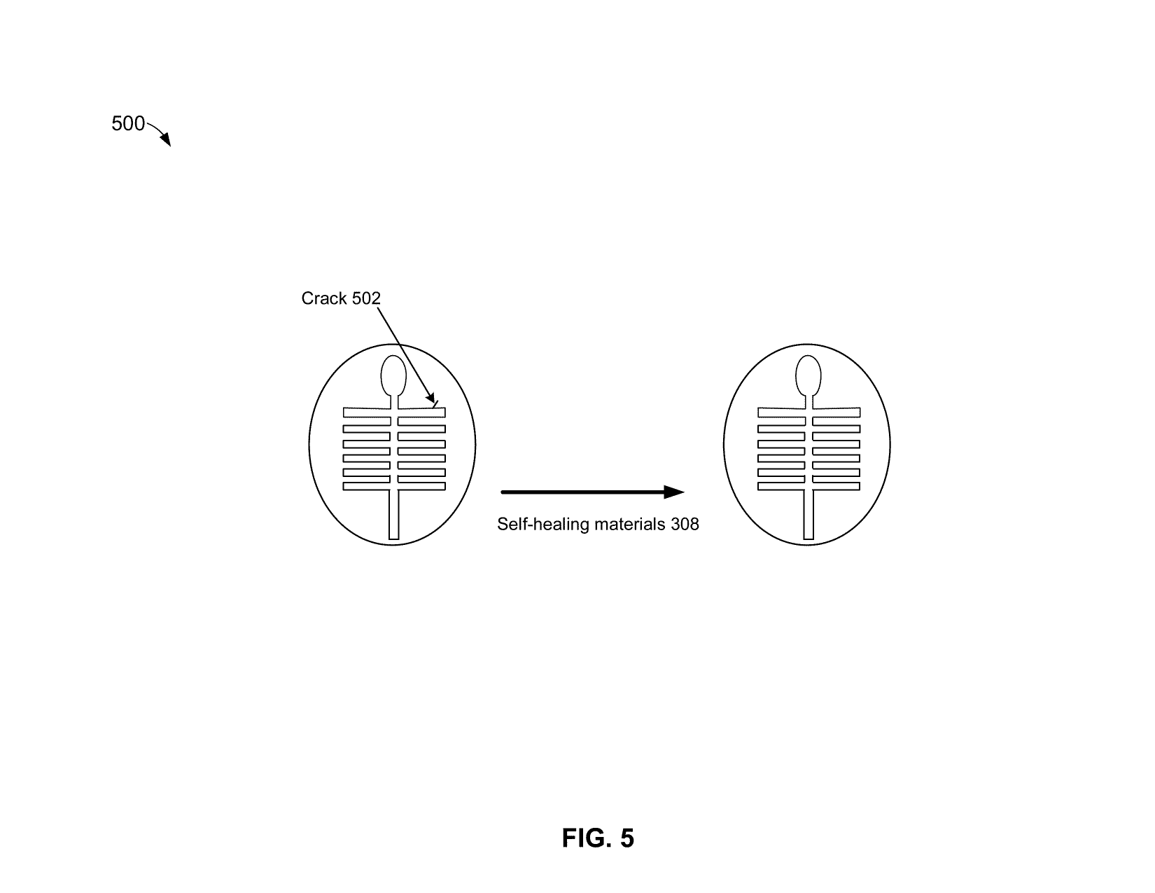

FIG. 3 is a diagram of an example implementation 300 associated with using a Kapton mask for manufacturing. Example implementation 300 shows a 4D printer 302 that prints a Kapton mask 304. Features of the Kapton mask 304 are described in more detail below in connection with FIGS. 4 and 5.

In some aspects, a computer system (e.g., computer 102) may design the Kapton mask 304, as shown by reference number 305. The computer system may use a 3D model to optimize aperture size and pattern density. The 3D model may be created using computer-aided design (CAD) software. The Kapton mask 304 may be designed with areas to be adjustable during manufacturing or use. The computer system may ensure that the Kapton mask 304 meets required specifications.

In some aspects, the computer system may generate a digital twin of the Kapton mask 304 for simulating behavior of the mask and for optimizing the design of the mask. For example, the digital twin can be used to simulate various environmental conditions and to predict potential failure modes, such as cracking or deformation. The digital twin may be used to simulate a dimensional stability of apertures in the Kapton mask 304 when using different shape-memory alloys. The computer system may analyze stress distribution across materials when different properties of the shape-memory alloys are activated. The computer system may optimize material selections to minimize material stresses.

By creating a virtual replica of the Kapton mask 304, the computer system may simulate the behavior of different shape-memory alloys and predict potential failure modes, such as radial cracking or circumferential yielding, that may occur during various manufacturing processes. This allows for the evaluation of different design scenarios and the optimization of material selections to minimize material stresses, ultimately improving the reliability of the Kapton mask.

In an example, the construction of the digital twin involves a multi-step process, beginning with the collection of material characterization data through techniques such as tensile testing, dynamic mechanical analysis, and thermomechanical analysis. Geometric characterization data is also gathered using optical metrology and digital image correlation. Additionally, data related to the effects of various manufacturing processes, operational testing, and accelerated aging tests is collected and used to validate the digital twin.

To ensure the accuracy of the digital twin, a rigorous implementation approach is employed. This may involve conducting baseline characterization tests, controlled variation studies, and multi-factor analyses to develop a comprehensive understanding of the material properties and behavior. The computer system may refine the model of the digital twin through a comparison of predicted and actual test results. The computer system may also use machine learning algorithms to improve the model’s predictive capabilities.

The use of a digital twin in this context enables the rapid testing and evaluation of different design scenarios, allowing for the optimization of material selections and the minimization of material stresses. This, in turn, improves the reliability of the Kapton mask and reduces the likelihood of failures during the manufacturing process. Furthermore, the digital twin enables the prediction of process parameters, such as temperature excursions and ramp rates, that can be used to minimize transient stresses and ensure the optimal performance of the smart materials.

A main benefit of the digital twin is its ability to reveal structural and chemical information about the material without destructive testing, using techniques such as Micro-Raman spectroscopy. This allows for high-resolution stress mapping and provides valuable insights into the material’s behavior under different conditions. By leveraging these insights, manufacturers can design and develop more robust and reliable Kapton masks, ultimately improving the overall efficiency and effectiveness of the semiconductor manufacturing process.

The Kapton mask 304 may be designed to dynamically respond to environmental stimuli. Embedded smart materials, such as thermoresponsive polymers, allow the mask to alter its physical properties, including shape and aperture size, in response to temperature changes. For example, during a thermal deposition process, the Kapton mask 304 may expand to accommodate different deposition zones or contract to improve pattern resolution. The Kapton mask 304 may also respond to UV light for photolithography processes by altering its transparency or structure, enabling the mask to adjust dynamically during different phases of the semiconductor manufacturing process.

As shown by reference number 310, the computer system may control 4D printing of the Kapton mask 304 using the 4D printer 302 based on the design. The 4D printing process allows for the creation of complex geometries and structures. The 4D printer may be a multi-material printer, where the printed mask can be tailored with different material properties in different regions, creating areas that respond differently to stimuli.

The 4D printer 302 starts with Kapton as the primary material, for its high thermal stability and mechanical strength, making the mask suitable for high-temperature environments (a common requirement in semiconductor deposition processes). The 4D printer 302 can embed smart materials 306 and a self-healing polymer 308 into the Kapton. There may be a plurality of smart materials embedded within the Kapton, each configured to respond to a different external stimulus, including temperature, pressure, and UV light. Self-healing polymers can be used to automatically repair physical damage caused by manufacturing or use, such as cracks or breaks in the Kapton mask 304 that are created during repetitive deposition cycles or extreme conditions (e.g., plasma etching). The self-healing polymer 308 may include microcapsules that are designed to rupture when a crack forms, releasing a healing agent to repair the damage.

In an example, the fabrication of the dynamic Kapton mask 304 involves a multi-step process that leverages the capabilities of both traditional 3D printing and advanced 4D printing techniques. Initially, the base structure of the mask is printed using a traditional 3D printer, carefully crafting the mechanical properties necessary for withstanding the demands of deposition, such as heat resistance and flexibility. Next, 4D printing techniques are employed to embed actuators and smart materials, including shape-memory alloys and thermoresponsive polymers, into the mask. These materials are strategically positioned in areas where adaptability to external stimuli, such as heat, is crucial. The shape-memory alloys enable the mask’s apertures to expand or contract in response to temperature fluctuations, while the thermoresponsive polymers allow specific regions of the mask to change shape or hardness as needed. Following the printing process, the mask undergoes post-processing, where the mask is exposed to external stimuli to activate the smart materials, and then calibrated to ensure optimal performance under real deposition conditions. By fine-tuning the mask’s properties through additional printing or post-processing steps, its responsiveness can be precisely tailored to meet the requirements of the deposition process.

The Kapton mask 304 may also have a dynamic thermal conductivity, which allows the mask to adjust its heat dissipation properties. This ensures that the Kapton mask 304 can maintain structural integrity even under extreme deposition conditions, such as those involving high-energy ion beams or plasma processes. The Kapton mask 304 will protect sensitive regions of the wafer while dissipating excess heat to avoid damage during high-temperature deposition steps.

In some aspects, the Kapton mask 304 may include a mechanism for adjusting material permeability based on external electrical inputs or temperature. For example, the mechanism can be used to adjust the material permeability of the Kapton mask 304 in response to changing environmental conditions. The Kapton mask 304 is capable of performing multiple functions in a single tool. By altering its material permeability in response to applied electrical fields or temperature changes, the Kapton mask 304 may control the deposition of various materials (e.g., metals, insulators) and even allow for doping during the same process. This reduces the number of tools required, streamlining the manufacturing process and lowering operational costs.

As shown by reference number 315, the computer system may use the Kapton mask for deposition, to create an object 312 such as a semiconductor circuit. In some implementations, the Kapton mask 304 may include shape-memory materials or programmable polymers. For example, these materials can change shape in response to temperature or light, enabling the mask to adapt to changing environmental conditions during the deposition process.

FIG. 4 is a diagram illustrating an example 400 of adjusting the Kapton mask. The Kapton mask 304 is designed to be dynamic, self-healing, and multi-functional, with properties that can be adjusted in real-time. In example 400, the Kapton mask 304 may be used for deposition processes, specifically in semiconductor manufacturing. The Kapton mask 304 may include sensors 402 and a control system 404. The computer system may use the sensors 402 and the control system 404 to monitor the Kapton mask 304, as shown by reference number 405. The sensors 402 provide feedback to the control system 404, which uses real-time data to adjust the mask’s shape and material properties as needed. This allows for precise control and adaption during the deposition process.

The Kapton mask 304 may include smart materials responsive to temperature, pressure, or ultraviolet light. As shown by reference number 410, the computer system may use external stimuli of the smart materials and/or the control system 404 to adjust the size and shape of the Kapton mask 304 or apertures of the Kapton mask 304. The monitoring and adjusting ensures consistent performance and prevents defects during the deposition.

In some implementations, the Kapton mask 304 has a capability of automatically adjusting its size and shape in response to changing environmental conditions (e.g., temperature and light) during deposition. This feature enables the mask to always provide optimal deposition results, even in complex or high-precision applications.

Additionally, or alternatively, the Kapton mask 304 may be capable of dynamic adjustment of its material permeability. For example, the material permeability may be adjusted based on external electrical inputs or temperature, enabling precise control over the deposition process.

The Kapton mask 304 has the ability to self-adjust its apertures in response to temperature changes during deposition, allowing it to seamlessly adapt to different deposition methods without manual intervention. Moreover, the mask can be programmed to change its shape and patterning properties in real-time, enabling the creation of multiple deposition patterns without the need for mask swapping. This precision and adaptability enable atomic-level deposition accuracy, crucial for working with 2 nm chips, while ensuring consistency across the wafer even in regions with varying thermal or mechanical conditions. The mask’s thermal management capabilities also ensure its structural integrity during high-energy deposition processes, dynamically adjusting its thermal conductivity to protect sensitive areas. The applications of this technology in semiconductor manufacturing may include adaptable masking for multi-stage deposition, reduced tool changes, and minimized waste. By utilizing a single dynamic mask, manufacturers can streamline their production process, lower costs, and reduce material waste, making the dynamic mask an invaluable asset in the pursuit of smaller, more complex chip designs.

FIG. 5 is a diagram illustrating an example 500 of a self-healing crack. Example 500 shows that the self-healing polymer 308 of the Kapton mask 304 may include a polymer with microcapsules that, in the case of a crack 502, can automatically heal the crack to achieve increased structural integrity.

The multi-functionality of the dynamic, self-healing Kapton mask 304 enables the mask to perform multiple tasks, such as deposition and doping, thereby reducing the need for multiple specialized masks. This simplification of the manufacturing process leads to lower operational costs, faster production cycles, and quicker turnaround times for 2 nm designs.

In addition to improving efficiency and reducing costs, the dynamic Kapton mask 304 also enhances yield and precision. The real-time adaptive control system ensures that the mask continuously adjusts to changing deposition conditions, maintaining high precision and reducing defects during the deposition process. This is particularly helpful for 2 nm technology, where even the smallest deviations can result in defects or chip failures. By maintaining consistent high-quality output, the dynamic, self-healing Kapton mask 304 leads to improved yield and reduced scrap rates, directly impacting the profitability of advanced chip manufacturing.

The self-healing capabilities of the Kapton mask 304 also extend its operational life, reducing the need for frequent replacement and minimizing downtime. This durability is useful for 2 nm manufacturing, where the demands on the mask are extreme. By extending the lifespan of the mask, the dynamic, self-healing Kapton mask 304 reduces maintenance costs and interruptions in manufacturing flow, resulting in longer mask lifecycles and improved overall efficiency.

Furthermore, the multi-stimuli responsive nature of the dynamic, self-healing Kapton mask 304 allows the mask to adapt to a variety of deposition techniques, reducing the need for multiple specialized masks. This versatility enables manufacturers to rapidly pivot between processes, keeping up with the fast-paced evolution of semiconductor technologies. The 4D printing system for the dynamic, self-healing Kapton mask 304 also minimizes material waste by ensuring high-precision patterning and reducing defects, contributing to more efficient material use and delivering cost savings and environmental benefits.

Finally, the 4D printing system provides a scalable solution capable of adapting to increasingly sophisticated semiconductor manufacturing processes. As manufacturers progress toward even smaller nodes, such as 1.5 nm and smaller, the integration of smart materials and real-time adjustments prepares the mask for future technological advancements.

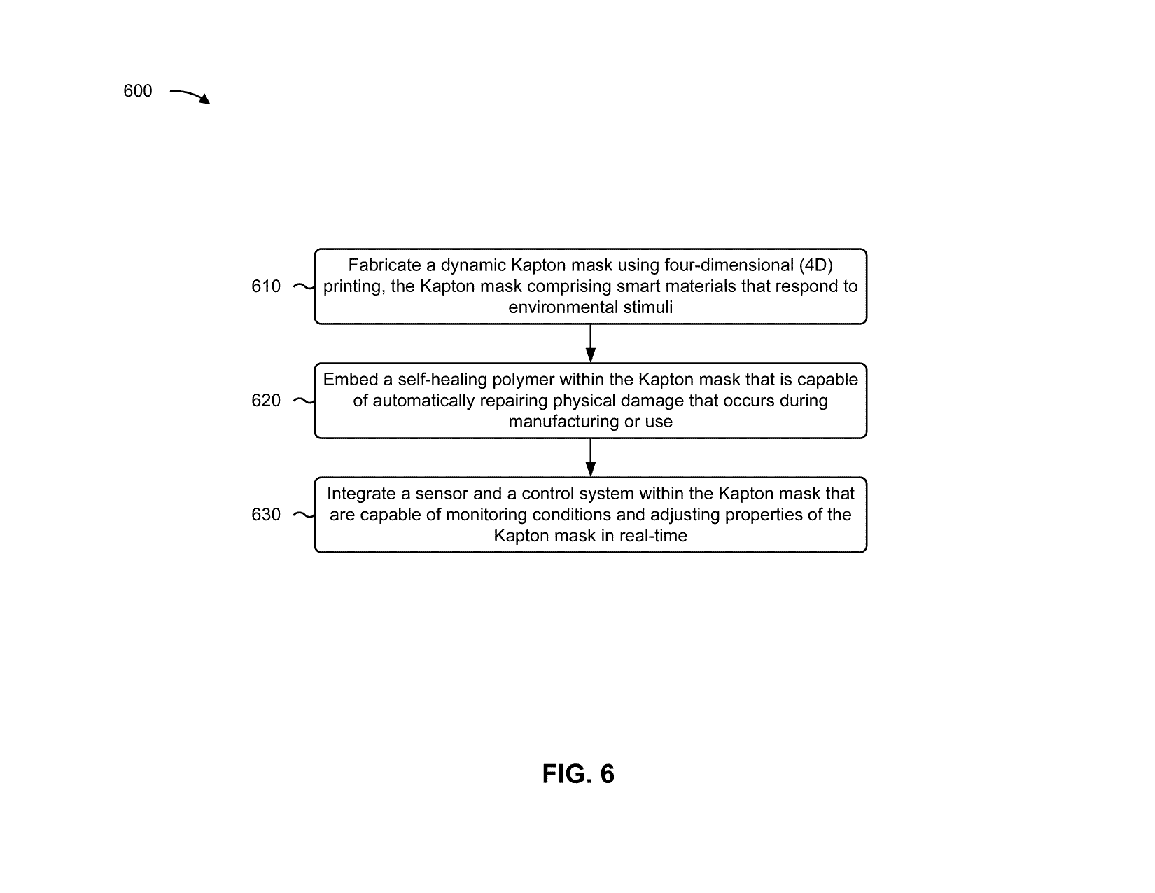

FIG. 6 is a flowchart of an example process 600 associated with a 4D printed dynamic, self-healing Kapton mask. One or more process blocks of FIG. 6 are performed by a computer system (e.g., computer 102) and/or by another device or a group of devices separate from or including the computer system.

As shown in FIG. 6, process 600 includes fabricating a dynamic Kapton mask using 4D printing, the Kapton mask comprising smart materials that respond to environmental stimuli (block 610). For example, the computer system may fabricate a dynamic Kapton mask using 4D printing, the Kapton mask comprising smart materials that respond to environmental stimuli, as described above.

As further shown in FIG. 6, process 600 includes embedding a self-healing polymer within the Kapton mask that is capable of automatically repairing physical damage that occurs during manufacturing or use (block 620). For example, the computer system may embed a self-healing polymer within the Kapton mask that is capable of automatically repairing physical damage that occurs during manufacturing or use, as described above.

As further shown in FIG. 6, process 600 includes integrating a sensor and a control system within the Kapton mask that are capable of monitoring conditions and adjusting properties of the Kapton mask in real-time (block 630). For example, the computer system may integrate a sensor and a control system within the Kapton mask that are capable of monitoring conditions and adjusting properties of the Kapton mask in real-time, as described above.

Process 600 may include additional aspects, such as any single aspect or any combination of aspects described below and/or in connection with one or more other processes described elsewhere herein.

In a first aspect, process 600 includes using the Kapton mask in a manufacturing process, wherein the Kapton mask is capable of adapting to changing environmental conditions during the manufacturing or use.

In a second aspect, alone or in combination with the first aspect, process 600 includes using the Kapton mask to perform 4D printing of an object.

In a third aspect, alone or in combination with one or more of the first and second aspects, process 600 includes adjusting, using the sensor and the control system, an aperture size and a shape of the Kapton mask in real-time.

In a fourth aspect, alone or in combination with one or more of the first through third aspects, the Kapton mask is scalable for use in semiconductor manufacturing processes, and the Kapton mask is capable of adapting to changing environmental conditions to ensure precise deposition control.

In a fifth aspect, alone or in combination with one or more of the first through fourth aspects, the control system uses real-time data from the sensor to adjust the properties to ensure the precise deposition control.

In a sixth aspect, alone or in combination with one or more of the first through fifth aspects, the Kapton mask is capable of dynamically adjusting its material permeability for deposition and doping.

In a seventh aspect, alone or in combination with one or more of the first through sixth aspects, the self-healing polymer includes microcapsules containing a healing agent that is released upon crack formation.

In an eighth aspect, alone or in combination with one or more of the first through seventh aspects, the Kapton mask has a dynamic thermal conductivity to adjust heat dissipation properties during high-energy deposition processes.

In a ninth aspect, alone or in combination with one or more of the first through eighth aspects, process 600 includes generating a digital twin of the Kapton mask to simulate behavior of the Kapton mask and to optimize a design of the Kapton mask.

In a tenth aspect, alone or in combination with one or more of the first through ninth aspects, process 600 includes predicting potential failure modes of the Kapton mask, and optimizing material selections such that material stresses are minimized.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

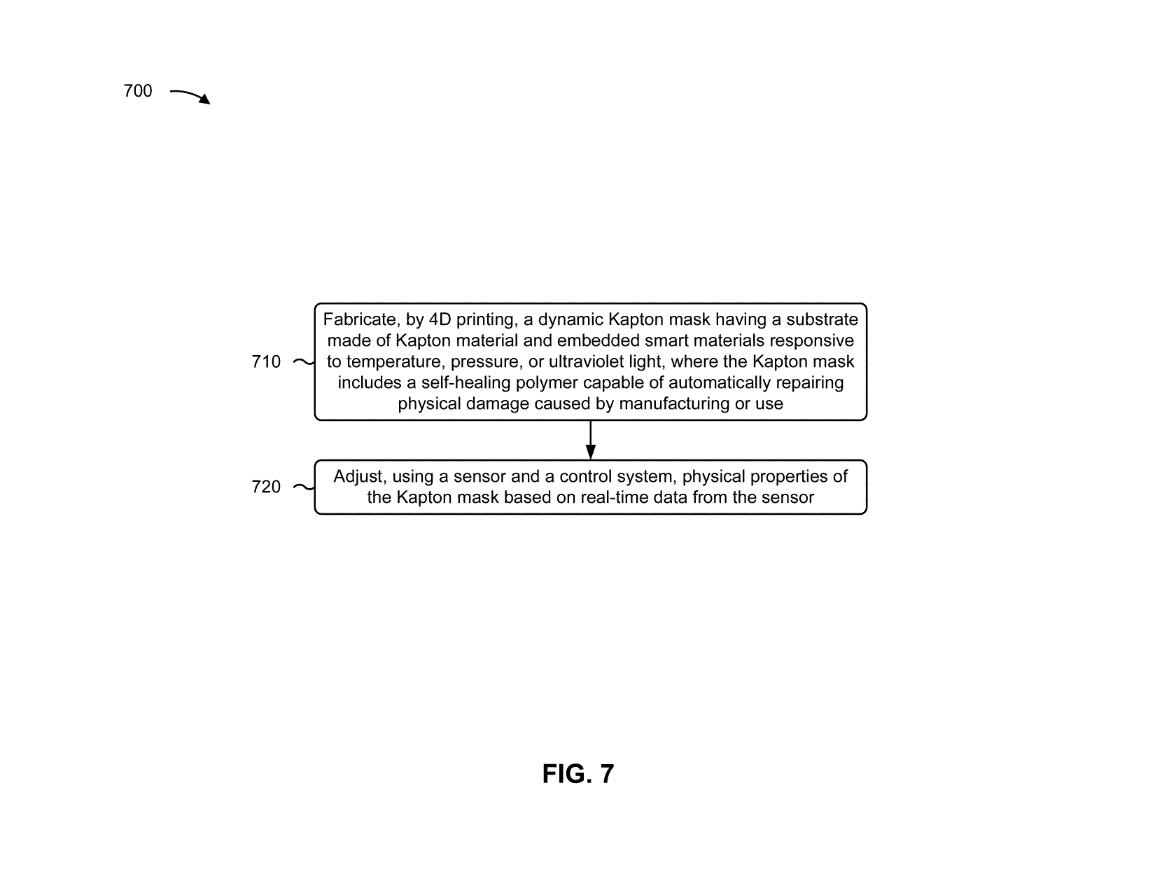

FIG. 7 is a flowchart of an example process 700 associated with a 4D printed dynamic self-healing Kapton mask. One or more process blocks of FIG. 7 are performed by a computer system (e.g., computer 102) and/or by another device or a group of devices separate from or including the computer system.

As shown in FIG. 7, process 700 includes fabricating, by 4D printing, a dynamic Kapton mask having a substrate made of Kapton material and embedded smart materials responsive to temperature, pressure, or ultraviolet light, where the Kapton mask includes a self-healing polymer capable of automatically repairing physical damage caused by manufacturing or use (block 710). For example, the computer system may fabricate, by 4D printing, a dynamic Kapton mask having a substrate made of Kapton material and embedded smart materials responsive to temperature, pressure, or ultraviolet light, where the Kapton mask includes a self-healing polymer capable of automatically repairing physical damage caused by manufacturing or use, as described above.

As further shown in FIG. 7, process 700 includes adjusting, using a sensor and a control system, physical properties of the Kapton mask based on real-time data from the sensor (block 720). For example, the computer system may adjust, using a sensor and a control system, physical properties of the Kapton mask based on real-time data from the sensor, as described above.

Process 700 may include additional aspects, such as any single aspect or any combination of aspects described below and/or in connection with one or more other processes described elsewhere herein.

In a first aspect, the operations further comprise designing the Kapton mask with a 3D model based on aperture size, pattern density, and areas to be adjustable during the manufacturing or use, indicating shape-memory materials or programmable polymers that are to change shape in response to temperature or light, and printing the Kapton mask using a multi-material 3D printer that combines Kapton with the smart materials in precise layers.

In a second aspect, alone or in combination with the first aspect, the manufacturing or use includes semiconductor manufacturing using a deposition process, an etching process, or a plasma process.

In a third aspect, alone or in combination with one or more of the first and second aspects, the operations further comprise generating a digital twin of the Kapton mask that simulates a dimensional stability of the Kapton mask.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

The foregoing disclosure provides illustration and description, but is not intended to be exhaustive or to limit the implementations to the precise forms disclosed. Modifications may be made in light of the above disclosure or may be acquired from practice of the implementations. For example, various aspects of this disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

A computer program product embodiment (“CPP embodiment” or “CPP”) is a term used in this disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, RAM, ROM, erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc), or any suitable combination of the foregoing. A computer-readable storage medium, as that term is used in this disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code - it being understood that software and hardware can be used to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When “a processor” or “one or more processors” (or another device or component, such as “a controller” or “one or more controllers”) is described or claimed (within a single claim or across multiple claims) as performing multiple operations or being configured to perform multiple operations, this language is intended to broadly cover a variety of processor architectures and environments. For example, unless explicitly claimed otherwise (e.g., via the use of “first processor” and “second processor” or other language that differentiates processors in the claims), this language is intended to cover a single processor performing or being configured to perform all of the operations, a group of processors collectively performing or being configured to perform all of the operations, a first processor performing or being configured to perform a first operation and a second processor performing or being configured to perform a second operation, or any combination of processors performing or being configured to perform the operations. For example, when a claim has the form “one or more processors configured to: perform X; perform Y; and perform Z,” that claim should be interpreted to mean “one or more processors configured to perform X; one or more (possibly different) processors configured to perform Y; and one or more (also possibly different) processors configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method comprising:
fabricating a dynamic Kapton mask using four-dimensional (4D) printing, the Kapton mask comprising smart materials that respond to environmental stimuli;
embedding a self-healing polymer within the Kapton mask that is capable of automatically repairing physical damage that occurs during manufacturing or use; and
integrating a sensor and a control system within the Kapton mask that are capable of monitoring conditions and adjusting properties of the Kapton mask in real-time.

2. The method of claim 1, further comprising using the Kapton mask in a manufacturing process, wherein the Kapton mask is capable of adapting to changing environmental conditions during the manufacturing or use.

3. The method of claim 1, further comprising using the Kapton mask to perform 4D printing of an object.

4. The method of claim 1, further comprising adjusting, using the sensor and the control system, an aperture size and a shape of the Kapton mask in real-time.

5. The method of claim 1, wherein the Kapton mask is scalable for use in semiconductor manufacturing processes, and wherein the Kapton mask is capable of adapting to changing environmental conditions to ensure precise deposition control.

6. The method of claim 5, wherein the control system uses real-time data from the sensor to adjust the properties to ensure the precise deposition control.

7. The method of claim 1, wherein the Kapton mask is capable of dynamically adjusting its material permeability for deposition and doping.

8. The method of claim 1, wherein the self-healing polymer includes microcapsules containing a healing agent that is released upon crack formation.

9. The method of claim 1, wherein the Kapton mask has a dynamic thermal conductivity to adjust heat dissipation properties during high-energy deposition processes.

10. The method of claim 1, further comprising:
generating a digital twin of the Kapton mask to simulate behavior of the Kapton mask and to optimize a design of the Kapton mask.

11. The method of claim 10, further comprising:
predicting potential failure modes of the Kapton mask; and
optimizing material selections such that material stresses are minimized.

12. A device comprising:
a Kapton mask that includes smart materials configured to respond to external stimuli that include temperature, pressure, or ultraviolet light, wherein the Kapton mask includes a self-healing polymer capable of repairing physical damage caused by manufacturing or use; and
a set of sensors integrated into the Kapton mask that are configured to monitor, during the manufacture or use, environmental conditions that include temperature, pressure, and contamination level.

13. The device of claim 12, wherein the device is configured to adjust a material permeability of the Kapton mask based on external electrical inputs or temperature.

14. The device of claim 12, wherein the self-healing polymer is capable of automatically repairing physical damage caused by a deposition process, an etching process, or a plasma process.

15. The device of claim 12, wherein the Kapton mask includes dynamic thermal conductivity that is capable of adjustment of heat dissipation properties during high-energy deposition processes.

16. The device of claim 12, wherein the device is configured to generate a digital twin of the Kapton mask that simulates a dimensional stability of apertures in the Kapton mask when using different shape-memory alloys and stress distribution across materials when different properties of the shape-memory alloys are activated.

17. A computer program product comprising:
one or more computer-readable storage media; and
program instructions stored on the one or more computer-readable storage media to perform operations comprising:
fabricating, by four-dimensional (4D) printing, a dynamic Kapton mask having a substrate made of Kapton material and embedded smart materials responsive to temperature, pressure, or ultraviolet light, wherein the Kapton mask includes a self-healing polymer capable of automatically repairing physical damage caused by manufacturing or use; and
adjusting, using a sensor and a control system, physical properties of the Kapton mask based on real-time data from the sensor.

18. The computer program product of claim 17, wherein the operations further comprise:
designing the Kapton mask with a three-dimensional (3D) model based on aperture size, pattern density, and areas to be adjustable during the manufacturing or use;
indicating shape-memory materials or programmable polymers that are to change shape in response to temperature or light; and
printing the Kapton mask using a multi-material 3D printer that combines Kapton with the smart materials in precise layers.

19. The computer program product of claim 17, wherein the manufacturing or use includes semiconductor manufacturing using a deposition process, an etching process, or a plasma process.

20. The computer program product of claim 17, wherein the operations further comprise:
generating a digital twin of the Kapton mask that simulates a dimensional stability of the Kapton mask.
